(19) United States
(12) Patent Application Publication
(10) Pub. No.: US 2025/0289403 A1
(43) Pub. Date: Sep. 18, 2025

(54) ELECTRONIC CONTROL UNIT, BRAKE ASSEMBLY AND BRAKE SYSTEM

(71) Applicant: Continental Automotive Technologies GmbH, Hannover (DE)

(72) Inventors: Michael Jürgens, Woelfersheim/Wetterau (DE); Robert Scheffel, Frankfurt am Main (DE)

(73) Assignee: Continental Automotive Technologies GmbH, Hannover (DE)

(21) Appl. No.: 18/860,362

(22) PCT Filed: Apr. 14, 2023
(86) PCT No.: PCT/DE2023/200076

§ 371 Date: Oct. 25, 2024

(30) Foreign Application Priority Data
Apr. 26, 2022 (DE) 10 2022 204 012.0

(51) Int. Cl. B60T 8/171; B60T 13/74; F16D 51/22; F16D 65/22; F16D 66/00; H05K 5/00

(52) U.S. Cl. CPC B60T 8/171; B60T 13/746; F16D 51/22; F16D 65/22; F16D 66/00; H05K 5/0047; F16D 2066/003; F16D 2066/005; F16D 2066/006

(57) ABSTRACT

A control unit for a drum brake is provided. The drum brake includes a spreader unit with a transmission, a motor, at least one coil, a force sensor, a ratchet wheel, and an angle sensor. The control unit includes a single main printed circuit board and the drum brake components are arranged in such a way that all the parts are connected directly to the printed circuit board).

### CROSS-REFERENCE TO RELATED APPLICATIONS

This application is a national stage application, filed under 35 U.S.C. § 371, of International Patent Application No. PCT/DE2023/200076, filed on Apr. 14, 2023, which is incorporated by reference herein in its entirety.

### TECHNICAL FIELD

The technical field relates generally to an electronic control unit for a drum brake.

### BACKGROUND

Electromobility is accompanied by a higher availability of redundant and efficient electrical power supply within vehicles. Therefore, it makes sense at this point to switch from a hydraulic brake to an electric brake. The use of a drum brake is ideal for this purpose. A control unit supplies electrical energy to an electric motor, processes signals from a force sensor and signals from a motor position sensor, and drives an electromagnetic coil. When several assemblies need to be electrically connected to form a control unit, complex leadframes (in order to connect several printed circuit boards), downstream wire welding processes and punctured contacts are commonly used. This procedure therefore involves a large number of individual parts and thus a large number of assembly process steps. There is also a similar concept based on a pure parking brake with a disk brake.

The previous architecture for control units of drum brakes is therefore complex and not particularly efficient, in particular in terms of assembly. Therefore, there is an opportunity to improve this architecture—and thus also the assembly process.

### SUMMARY

The disclosure presents a control unit, in particular for a drum brake. The drum brake includes the following assemblies:
a spreader unit with a transmission,
a motor,
at least one coil,
at least one force sensor,
a ratchet wheel, and
an angle sensor.
   The control unit includes a single main printed circuit board. The assemblies are arranged in such a way that all the parts are connected directly to the main printed circuit board.

Although the following embodiments refer to drum brakes, it is understood that the control unit may also be used in conjunction with or together with another brake, for example a disk brake. Instead of a spreader unit, for example, a rotation-translation converter with an actuator can be provided, which can press a friction lining against a friction partner.

It is to be understood here that, in particular, the electronic components of the parts are connected directly to the main printed circuit board. This applies, in particular, to the parts motor, coil, force sensor and angle sensor and the corresponding associated electronic components.

A main printed circuit board is to be understood here to mean a printed circuit board to which a plurality of electronic components are connected and which performs the primary, important calculations for controlling the actuation of the drum brake, in particular controlling the motor. The angle sensor can also include a printed circuit board, which however is then used solely for the angle sensor. The main printed circuit board in contrast is connected to a plurality of different electronic components and sends and receives signals.

An architecture which includes only one single main printed circuit board is possible owing to the solution described herein. The design is less complex and comprises fewer individual parts and assembly steps.

In one embodiment, the at least one force sensor is coupled to the main printed circuit board either via an electrical interface or via a sensory or magnetic interface. The electrical interface may be in the form of one or more direct electrical press-in contacts.

In one embodiment, the control unit has a housing composed of fiber-reinforced plastic or cast lightweight metal. Plastic advantageously reduces costs.

In one embodiment, the contact pins on the main printed circuit board have elongate press-in zones in order to be able to compensate for the tolerances occurring owing to the individual parts. In other words, the corresponding electronic components can have contact pins for making electrical contact with the main printed circuit board. This allows the electronic components, for example the angle sensor, to also be arranged somewhat remote from the main printed circuit board, and allows the distance to be bridged by the contact pins.

The press-in zones can particularly expediently be formed in an elongate manner, that is to say in the longitudinal direction of the contact pin, in the axial direction. This makes it possible to compensate for tolerances of the mechanical assemblies even more effectively. For this purpose, the extension of the press-in zones in the axial direction can correspond at least to the thickness of the main printed circuit board, preferably at least to 1.1 times and particularly preferably at least to 1.2 times the thickness of the main printed circuit board.

Subsequent cold welding may take place at the press-in zones. Cold welding is to be understood here to mean a flow of material under pressure. Owing to their larger contact surface and the subsequent cold welding, the press-in zones are more robust and better suited to axle applications. Axle application in this context means that the brakes are mounted directly on the vehicle axle (front and rear axle). This means that they are exposed to road loads without suspension.

In one embodiment, the one force sensor is embedded directly in the motor or arranged in a guide with little vibration. If the force sensor is embedded directly in the motor, it is particularly preferably secured by means of an adhesive. In particular, the sensor is preferably embedded by means of the adhesive when mounting the printed circuit board (PCB).

In a one embodiment, the at least one force sensor is arranged at the opposite shaft end of the motor. This results in advantages in terms of installation space that have an advantageous effect on the compatibility for the left-hand and the right-hand wheel.

In one embodiment, the connection plug of the unit is arranged centrally in the control unit. This ensures compatibility of the design for both sides of the vehicle, that is to say for a left-hand and a right-hand wheel.

In one embodiment, the angle sensor is either a magnetic sensor or a target wheel. The magnetic sensor may include a magnet at the shaft end of the motor and a sensor which measures the change in the magnetic field starting from the magnet. The target wheel may be a rotation angle sensor and is formed as a rotating metal plate. It may be segmented and inductively senses the rotation angle of the motor using a printed circuit board coil.

The control unit may be arranged in a housing or comprise a housing and/or be surrounded by said housing. The arrangement can preferably be designed here in such a way that non-destructive removal at least of the parts motor, coil, force sensor, angle sensor and/or the main printed circuit board from each other and/or from the housing is prevented. This can be assisted, for example, by appropriate design of the joining partners. As a result, non-destructive access to these components is not possible. Therefore, the invention can also make an important contribution to increasing security and, for example, be advantageous in terms of cyber security since it is very difficult to manipulate the electronic components.

The housing of the control unit may be closed by a cover, wherein the cover may be removed without destruction. As a result, the cover, which is typically manufactured from a plastic material for cost reasons, can also be very easily replaced with a cover composed of a more durable material, for example from a lightweight metal such as aluminum.

According to a further embodiment, the control unit and the housing are of mirror-symmetrical construction, in particular with regard to the mounting and connection elements. In this way, mounting on both a left-hand and on a right-hand wheel can be rendered possible, that is to say mutual mounting, without the need for mounting and connection elements or associated plugs or cables to be designed differently for mounting on a left-hand or a right-hand wheel. This yields further cost-saving potential.

According to a yet further embodiment, the main printed circuit board is arranged over or above the parts, that is to say above the motor, coil and/or sensors, as seen in the vertical direction in the mounted position on the wheel. In other words, these parts face the ground in the case of a main printed circuit board with an approximately horizontal orientation. As a result, the weight forces of these parts can be very easily borne by means of the housing and have very little impact on the main printed circuit board, which is practically lying on top. This is also considered to be positive against the background of arrangement close to a wheel since the control unit can also be part of the unsprung masses, as a result of which it can be subjected to stronger vibrations.

A further particular embodiment may provide that a plug connection module is arranged above the main printed circuit board as seen in the vertical direction. This modular design provides a high degree of flexibility and variability in terms of change.

The disclosure is further distinguished in that the main printed circuit board may be formed without passage openings going beyond electrically contacting the parts, for example for passing certain devices through. This has the advantage that, firstly, the main printed circuit board is not weakened by further passage openings or bores and, secondly, that as much of the available space on the main printed circuit board as possible can be utilized.

A brake assembly is also disclosed. The control unit of the brake assembly includes a housing composed of fiber-reinforced plastic and the brake assembly comprises a brake drum base plate and is designed in such a way that all the forces of the drive components are absorbed by the brake drum base plate.

A brake system comprising an above-described control unit is also disclosed.

### BRIEF DESCRIPTION OF THE DRAWINGS

Further embodiments can be found in the following description of exemplary embodiments with reference to figures.

In each case, schematically:

FIG. 1 shows a sectional view of an exemplary illustration of an electronic control unit according to a first embodiment,

FIG. 2 shows a sectional view of an exemplary illustration of the electronic control unit according to a second embodiment, and

FIG. 3 shows a sectional view of an exemplary illustration of the electronic control unit according to a third embodiment.

### DETAILED DESCRIPTION

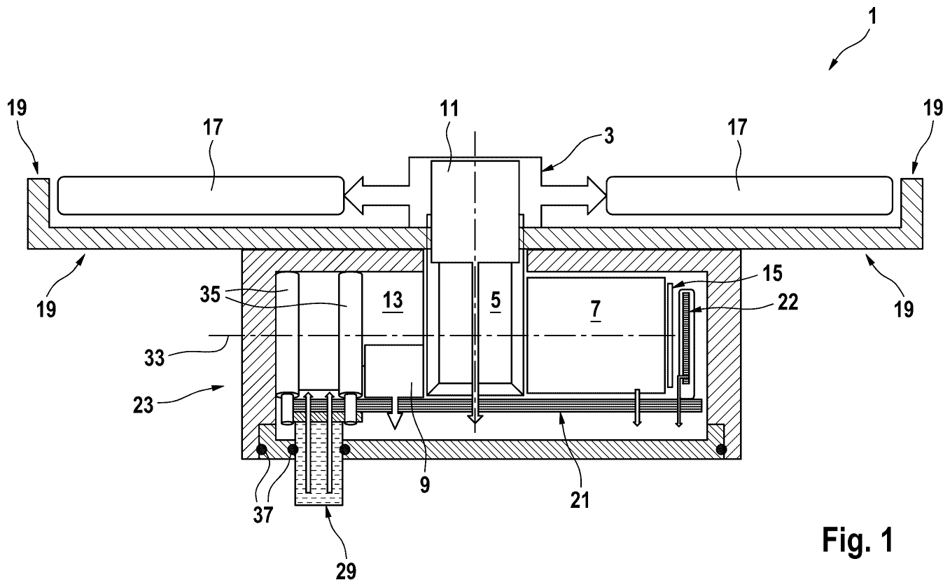

FIG. 1 shows a sectional view of an illustration of a first embodiment of an electronic control unit 1. The illustration shows the electronic control unit 1 for a drum brake (not numbered). The drum brake includes a spreader unit 3 with a transmission 5, a motor 7, at least one coil 9, at least one force sensor 11, a ratchet wheel 13 and a target wheel 15. The spreader unit 3 includes two brake shoes 17 with a brake lining (not visible) which press against a brake drum 19 during braking. As an alternative to the coil 9, a simple DC motor (not shown) can also be used. The electronic control unit 1 includes a main printed circuit board (“PCB”) 21 and a sensor PCB 22, which is overmolded and provided with press-in contacts (not shown). The sensor PCB (also known as the motor position PCB) 22 is a printed circuit board for detecting the motor angle position and is also used to control the motor position. It has an internal inductive coil (not shown). During braking, the spreader unit 3 is moved by way of the transmission 5 and the motor 7, and the brake shoes 17 are pressed against the brake drum. Data from the force sensor 11 is included in the process in order to set or adjust the desired braking force. The motor 7 is therefore actuated and thus the brake is applied by means of the signals from the printed circuit board 22. The ratchet wheel 13 has a coil (not shown). The force sensor 11 is situated over or under the transmission 5. The drive shaft is identified by reference numeral 33.

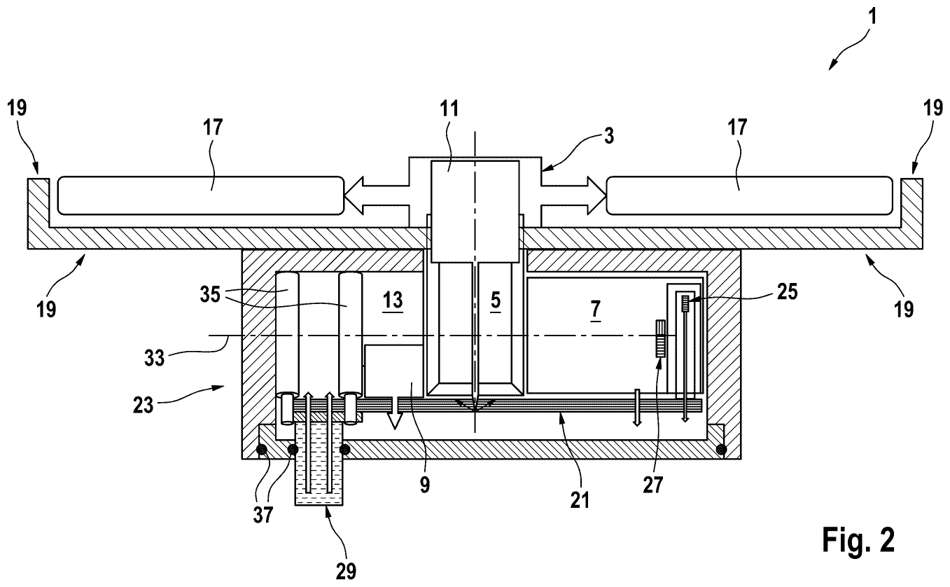

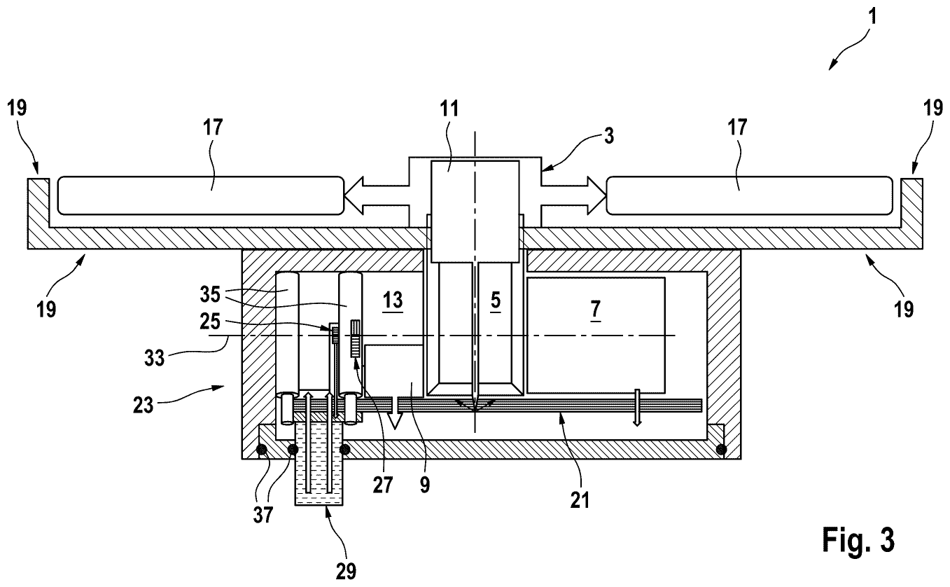

The target wheel 15 (rotation angle sensor) is a rotating metal plate. It is usually segmented and inductively senses the rotation angle using a PCB coil. As an alternative, a magnetic field sensor (see FIGS. 2 and 3) can be used.

The ratchet wheel 13 is a kind of gear. A pin (“pawl”) can “latch” linearly into the teeth through a solenoid coil and thus block the rotation of the gear. This prevents the brake from being released mechanically.

The assemblies are advantageously positioned such that they have their overall center of gravity centered with respect to the spreader unit 3. In one embodiment, all the parts are integrated in a housing 23 composed of fiber-reinforced plastic or cast lightweight metal. Thus, all the subcomponents (motor 7, transmission 5, coil 9, ratchet wheel 13, target wheel 15, main printed circuit board 21, and sensor printed circuit board 22) are, or will be, secured in the housing 23. The forces of the drive components may be absorbed by the brake drum base plate. For this purpose, the mechanical components are either screwed, clinched, welded, etc. to the brake drum base plate 19. In this case, the parts are therefore all individually connected to the brake drum base plate 19. This is done, for example, if the housing 23 is manufactured from plastic. Only the electronics (PCB and plug) are then “housed” in the plastic housing 23. As an alternative, the mechanical components are integrated into a metal housing 23. This (metal housing) for its part is then connected to the brake drum base plate 19.

The respective electrical contact-connections may be made by known press-fit technology in the PCB/main printed circuit board 21. As an alternative, other plug-in or special material-shaping contact techniques are also possible (welding, squeezing, etc.).

Contact pins with relatively long press-in zones may be used in order to be able to compensate for the XYZ tolerances occurring owing to the individual parts. For example, the press-in zone (Z direction) can have a length of 2 mm. Owing to their relatively large contact surface and the subsequent cold welding, the press-in zones are more robust and better suited to axle applications.

A combination of the target wheel 15 and the sensor printed circuit board coil in the sensor printed circuit board 22 is used as a sensor device in FIG. 1.

FIG. 2 shows a sectional view of an illustration of a second embodiment of the electronic control unit 1. Here, a motor sensor 25 can be embedded directly in the motor 7, for example by means of an adhesive. Thus, it is then part of the motor 7. This may be done when mounting the printed circuit board 21 (PCB). The motor sensor 25 may be designed as a magnetic sensor. As an alternative to adhesively bonding the sensor 25, it sits in a guide in the motor 7 with little vibration. The force sensor 11 is not electrically contacted, but rather has a sensory interface (see arrow pointing downward) at which mechanical relative movements are detected.

FIG. 3 shows a sectional view of an illustration of a third embodiment on. The motor sensor system 25 is positioned at the shaft end opposite the motor 7. The part identified by reference numeral 25 is an electronic part which detects the rotational position of the shaft end magnet 27. As a result, the entire assembly is arranged highly symmetrically with respect to the spreader unit 3. This provides advantages in terms of installation space in order to ensure a unit that is compatible with the left-hand and the right-hand wheel. In addition, the connection plug 29 of the unit is positioned centrally in the control unit 1. The housing 23, which consists of lightweight metal or plastic, can be closed by a cover 31 or is closed by a cover 31. This cover 31 also comprises plastic or metal (for example a metal sheet). When the housing 23 is closed by the cover 31, the control unit 1 is sealed. As an alternative, no cover is used, but rather a housing 23 which is sealed off with respect to the base plate 19 of the drum brake is used. As a further alternative, the control unit 1 can be clustered/split or divided into two separate sealed-off units. In a further alternative, the control unit 1 can be arranged on the brake drum base plate 19 rotated through 180°, so that the axis of the drive shaft 33 is not parallel to the base plate 19 but rather is positioned perpendicular to it. The sensors 11, 15, 25 may be coupled to the electronics system either via electrical direct press-in contacts or via a sensory or magnetic interface.

If the plug 29, as shown in FIG. 1, is part of the cover and pressed into the PCB 21, for example, then the PCB 21 has to be supported. The cylinders 35 thus prevent the PCB 21 from deflecting during the press-in process+center/guide the PCB 21 for the purpose of finding the press-in zones. The components drawn as black, filled circles in the figure are seals 37.

The individual design approaches described in the embodiments according to the figures can be combined with each other in any desired manner.

The disclosure describes a purely electromechanical wheel brake (without hydraulics) with a focus on the control unit, which is accompanied by increased market viability. For this purpose, a special arrangement of the assembly is proposed, which assists direct and simple electrical component control. The special combination or arrangement of the individual mechanical components enables a compact and variable system with only one (single) simple main printed circuit board for electronic wiring, which can be used compatibly on the left-hand and the right-hand wheel side owing to its axis of symmetry.

### LIST OF REFERENCE SIGNS

1 Control unit for a drum brake
3 Spreader unit
5 Transmission
7 Motor
9 Coil
11 Force sensor
13 Ratchet wheel
15 Target wheel
17 Brake shoes
19 Brake drum
21 Main printed circuit board
22 Sensor PCB
23 Housing
25 Motor sensor (magnetic sensor)
27 Shaft end magnet
29 Connection plug
31 Cover
33 Drive shaft
35 Cylinder
37 Seal

1-15. (canceled)

16. A control unit, in particular for a drum brake, the drum brake including a spreader unit with a transmission, a motor, at least one coil, a force sensor, a ratchet wheel, and an angle sensor, the control unit comprising:
a single main printed circuit board wherein electronic components of the motor, the at least one coil, the force sensor, and the angle sensor are connected directly to the main printed circuit board.

17. The control unit as claimed in claim 16, wherein the force sensor is connected to the main printed circuit board either via an electrical interface or via a sensory or magnetic interface.

18. The control unit as claimed in claim 16, wherein the control unit has a housing comprising fiber-reinforced plastic or cast lightweight metal.

19. The control unit as claimed in any claim 18 wherein the housing may be closed by a cover, and wherein the cover may be removed without destruction.

20. The control unit as claimed in claim 16, wherein contact pins on the main printed circuit board have elongate press-in zones in order to compensate for tolerances of the mechanical assemblies.

21. The control unit as claimed in claim 20, wherein the elongate press-in zones in the longitudinal direction corresponds at least to 1.2 times the thickness of the main printed circuit board.

22. The control unit as claimed in claim 16, wherein the force sensor is embedded directly in the motor.

23. The control unit as claimed in claim 16, wherein the angle sensor is either a magnetic sensor or a target wheel.

24. The control unit as claimed in claim 16, wherein the at least one angle sensor is a magnetic sensor and is arranged on an opposite shaft end of the motor.

25. The control unit as claimed in claim 16, further comprising a connection plug arranged centrally.

26. The control unit as claimed in claim 16, wherein non-destructive removal of the parts motor, the coil, the force sensor, the angle sensor, and/or the main printed circuit board is prevented.

27. The control unit as claimed in claim 16, wherein the control unit is mirror-symmetrical with regard to the mounting and connection elements.

28. The control unit as claimed in claim 16, wherein, in the mounted position, the main printed circuit board is arranged over or above the parts in the vertical direction.

29. The control unit as claimed in claim 16, wherein the main printed circuit board does not include any passage openings going beyond electrically contacting the parts.

30. A brake assembly comprising:
a spreader unit with a transmission,
a motor, at least one coil,
a force sensor,
a ratchet wheel,
an angle sensor, and
a control unit comprising
a single main printed circuit board wherein electronic components of the motor, the at least one coil, the force sensor, and the angle sensor are connected directly to the main printed circuit board, and
a housing composed of fiber-reinforced plastic, and
wherein the brake assembly includes a brake drum base plate designed in such a way that all the forces of the drive components are absorbed by the brake drum base plate.
